(19) United States
(12) Patent Application Publication
(10) Pub. No.: US 2008/0242096 A1
(43) Pub. Date: Oct. 2, 2008

(54) METHOD FOR PREPARING BOTTLE-SHAPED DEEP TRENCHES

(75) Inventor: Heng Kai Hsu, Hsinchu City (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., Hsinchu (TW)

(21) Appl. No.: 11/776,793

(22) Filed: Jul. 12, 2007

(30) Foreign Application Priority Data
Mar. 30, 2007 (TW) 096111202

(51) Int. Cl. H01L 21/311

(52) U.S. Cl. 438/701; 257/E21.231

(57) ABSTRACT

A method for preparing a bottle-shaped deep trench first forms a first mask with at least one opening on a substrate including a first epitaxy layer, an insulation layer on the first epitaxy layer and a second epitaxy layer on the insulation layer. A first etching process is performed to remove a portion of the substrate under the opening down to the interior of the insulation layer to form a trench, and a thermal treating process is then performed to form a second mask on the inner sidewall of the trench. Subsequently, a second etching process is performed to remove a portion of the substrate under the opening down to the interior of the first epitaxy layer to form a deep trench, and a third etching process is performed to remove a portion of the first epitaxy layer so as to form the bottle-shaped deep trench with an enlarged surface.

### BACKGROUND OF THE INVENTION

(A) Field of the Invention

The present invention relates to a method for preparing a bottle-shaped deep trench, and more particularly, to a method for preparing a bottle-shaped deep trench by using a silicon-on-insulator substrate to prevent the occurrence of over-etching.

(B) Description of the Related Art

There are two types of capacitors: the stacked capacitor and the deep trench capacitor. The stacked capacitor is fabricated directly on the surface of a silicon substrate, while the deep trench capacitor is fabricated inside the silicon substrate. The integration density of the DRAM has increased rapidly with recent innovations in semiconductor process technology, and the size of the memory cell, i.e., the size of the capacitor and the transistor, must be reduced correspondingly to achieve the purpose of high integration density. Since the capacitance is proportional to the surface area of an electrode of the capacitor, reducing the size of the capacitor will result in a decrease in capacitance, which makes it more difficult to correctly read data stored in the cell. Consequently, researchers developed a bottle-shaped deep trench capacitor which increases the inner surface area of the deep trench in the silicon substrate, in turn increasing the surface area of the electrode subsequently formed in the deep trench, thus increasing the capacitance.

FIG. 1 to FIG. 5 illustrate a method for preparing bottle-shaped deep trenches 10 in a silicon substrate 12 according to the prior art. A hard mask 18 including a silicon nitride layer 14 and a dielectric layer 16 is formed on the silicon substrate 12, and a lithographic process is then performed to form several openings in the hard mask 18. Subsequently, a dry etching process is performed by using the hard mask as the etching mask to form several trenches 22 in the silicon substrate 12 under the openings 20, as shown in FIG. 2.

Referring to FIG. 3, a thermal treating process such as the rapid thermal process is performed to form a silicon oxide layer on the inner sidewall of the trenches 22. By using the hard mask 16 and the silicon oxide layer 24 as the etching mask, another dry etching process is performed to increase the depth of the trenches 22 so as to create several deep trenches 26 in the silicon substrate 12 under the openings 20, as shown in FIG. 4. In particular, damaged regions 28 are easily formed in a certain portion of the silicon substrate 12 below the silicon oxide layer 24 since this portion of the silicon substrate 12 is located at the interface of the two dry etching process areas.

Referring to FIG. 5, a wet etching process is performed by using the hard mask 16 and the silicon oxide layer 24 as the etching mask to enlarge the area of the deep trenches 26 so as to form several bottle-shaped deep trenches 10 in the silicon substrate 12 under the openings 20. The conventional method forms the damaged regions 28 at the interface of the two dry etching process areas, the damaged regions 28 have a higher etch rate compared with other area and the subsequent wet etching processes remove the damaged regions 28 easily by over-etching such that the bottle-shaped deep trenches 10 are connected to each other rather than isolated from each other. As a result, the conductive layer, serving as the upper electrode of the trench capacitor, subsequently formed in the inner wall of the bottle-shaped deep trenches 10 will electrically connect to form a short circuit, and the trench capacitor will fail.

### SUMMARY OF THE INVENTION

One aspect of the present invention provides a method for preparing a bottle-shaped deep trench by using a silicon-on-insulator substrate to prevent the occurrence of over-etching.

A method for preparing a bottle-shaped deep trench according to this aspect of the present invention first forms a first mask with at least one opening on a substrate including a first epitaxy layer, an insulation layer on the first epitaxy layer and a second epitaxy layer on the insulation layer. A first etching process is performed to remove a portion of the substrate under the opening down to the interior of the insulation layer to form a trench, and a thermal treating process is then performed to form a second mask on the inner sidewall of the trench. Subsequently, a second etching process is performed to remove a portion of the substrate under the opening down to the interior of the first epitaxy layer to form a deep trench, and a third etching process is performed to remove a portion of the first epitaxy layer so as to form the bottle-shaped deep trench.

The conventional technique forms damaged regions at the interface of the two dry etching process areas, the damaged regions have a higher etch rate compared with other area and the subsequent wet etching processes remove the damaged regions easily by over-etching such that the bottle-shaped deep trenches are connected to each other rather than isolated from each other. In contrast, the present invention uses the silicon-on-insulator substrate to prepare the bottle-shaped deep trench and the interface of the two dry etching processes is controlled to be in the interior of the insulation layer of the silicon-on-insulator substrate. The subsequent wet etching process only selectively removes the first epitaxy layer of the silicon-on-insulator substrate, without etching the insulation layer substantially. Consequently, even if the two dry etching processes actually form a damaged region in the insulation layer, the subsequent wet etching process will not remove the damaged region in the insulation layer by over-etching. As a result, the present invention can prevent the bottle-shaped deep trenches from connecting to each other due to over-etching.

### BRIEF DESCRIPTION OF THE DRAWINGS

The objectives and advantages of the present invention will become apparent upon reading the following description and upon reference to the accompanying drawings in which:

FIG. 1 to FIG. 5 illustrate a method for preparing bottle-shaped deep trenches in a silicon substrate according to the prior art; and

FIG. 6 to FIG. 10 illustrate a method for preparing bottle-shaped deep trenches in a substrate according to one embodiment of the present invention.

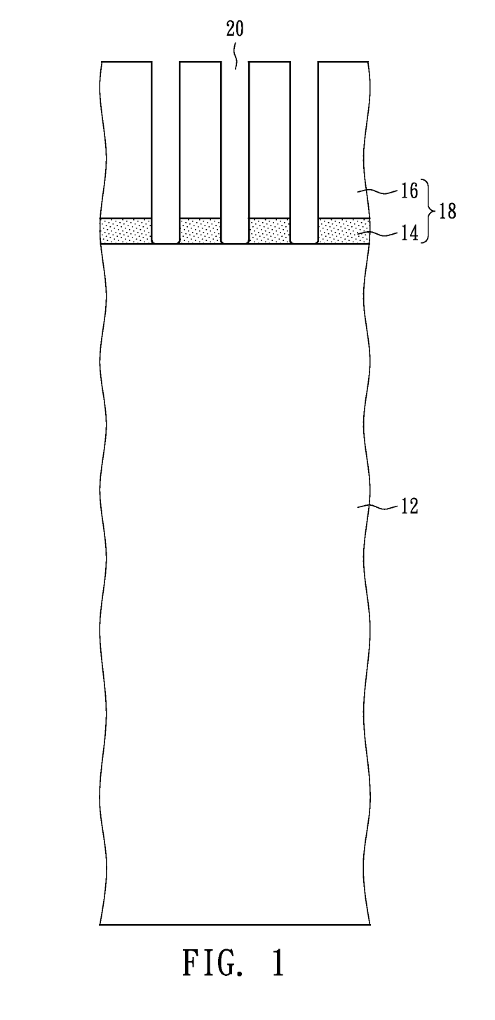

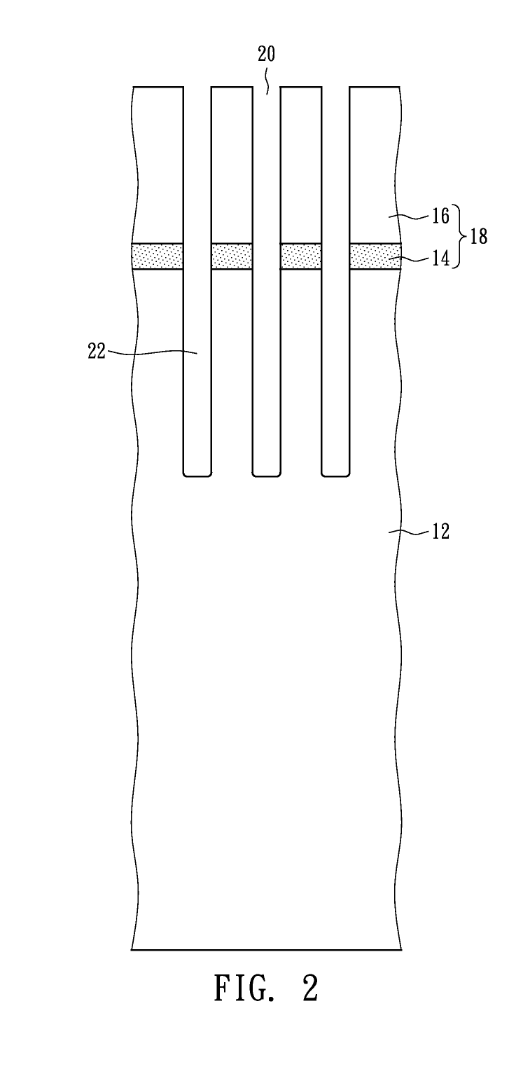

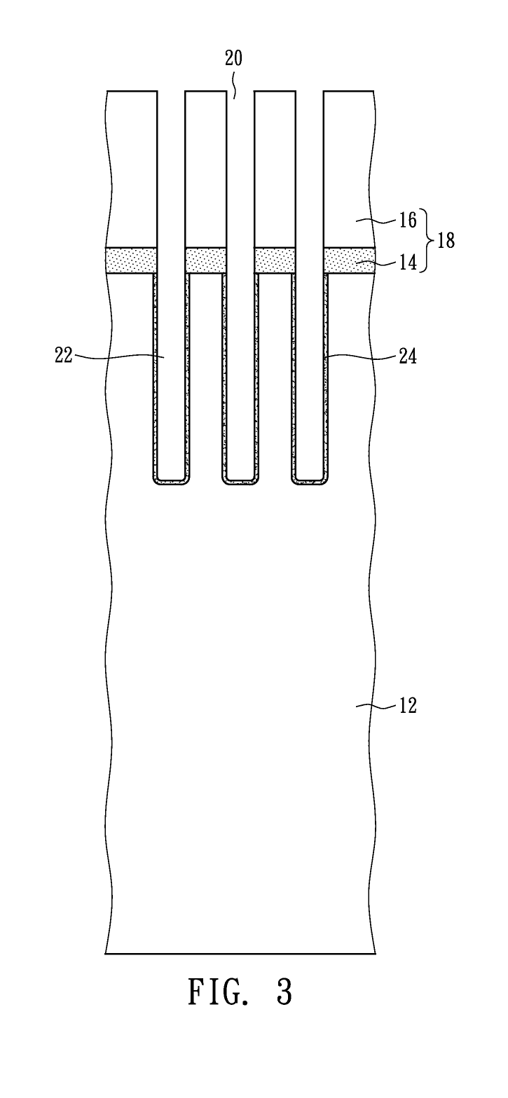

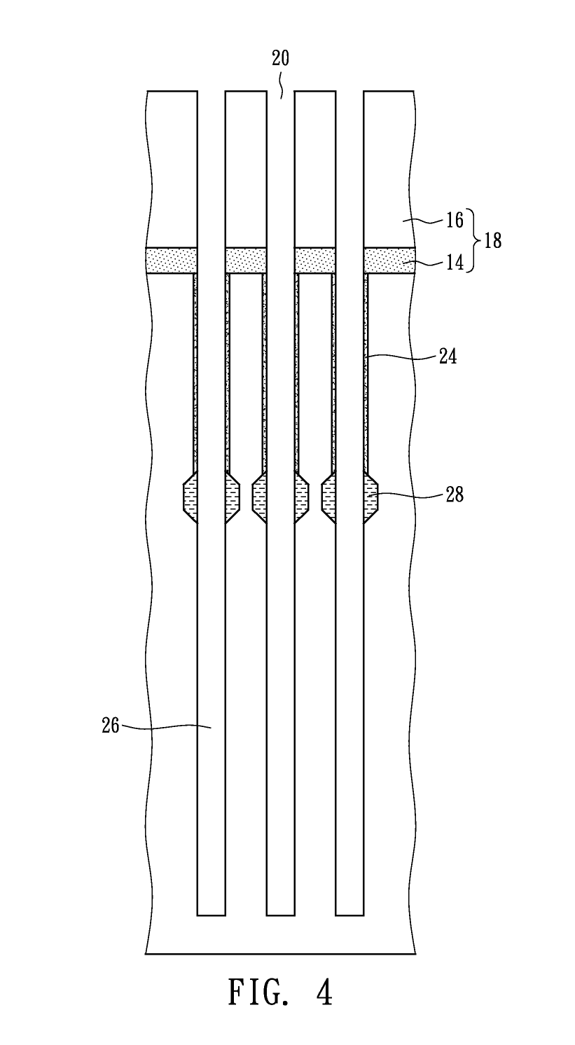

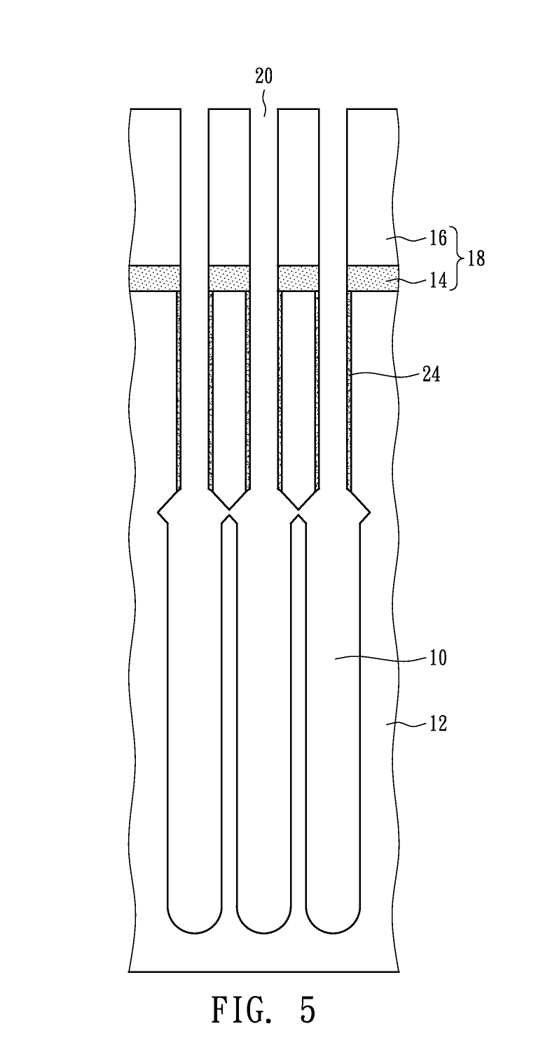

### DETAILED DESCRIPTION OF THE INVENTION

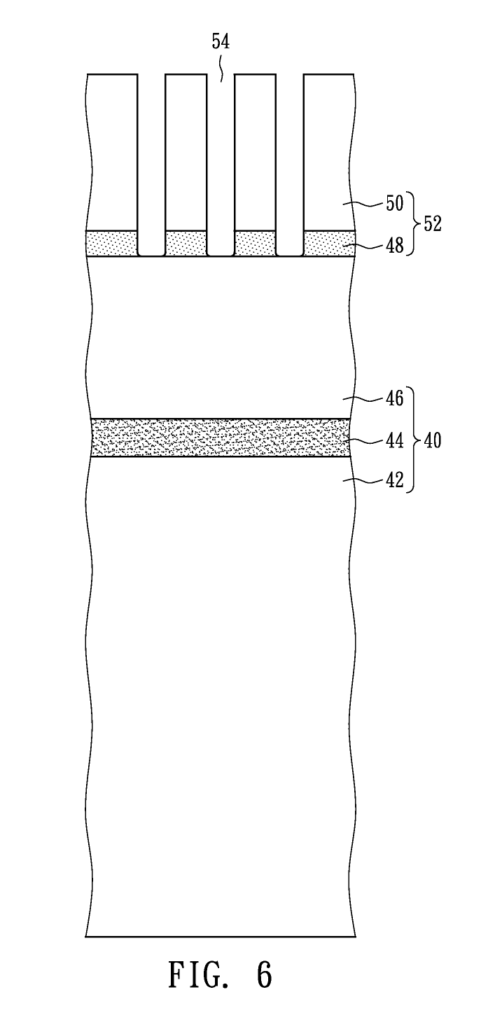

FIG. 6 to FIG. 10 illustrate a method for preparing bottle-shaped deep trenches 62 in a substrate 40 according to one embodiment of the present invention. A first mask 52 with several openings 54 is formed on the substrate 40, which is a silicon-on-insulator substrate including a first epitaxy layer 42, an insulation layer 44 on the first epitaxy layer 42 and a second epitaxy layer 46 on the insulation layer 44. The first epitaxy layer 42 and the second epitaxy layer 46 can be single crystal silicon layers, and the insulation layer 44 can be a silicon oxide layer. To prepare the first mask 52, the deposition process can be performed to form a silicon nitride layer 48 on the second epitaxy layer 46 and a dielectric layer 50 on the silicon nitride layer 48, and a lithographic process is then performed to form the openings 54 in the first mask 52 including the silicon nitride layer 48 and the dielectric layer 50, wherein the dielectric layer 50 can be a borosilicate glass layer.

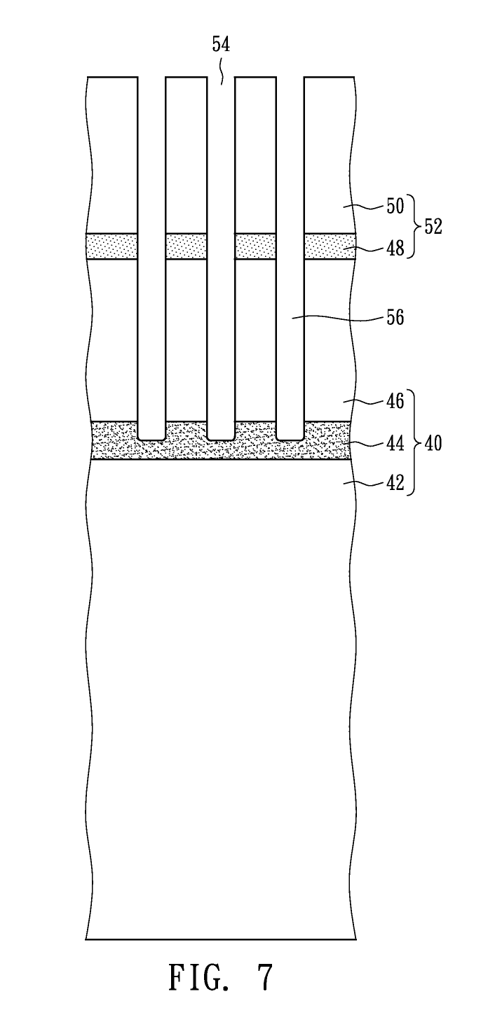

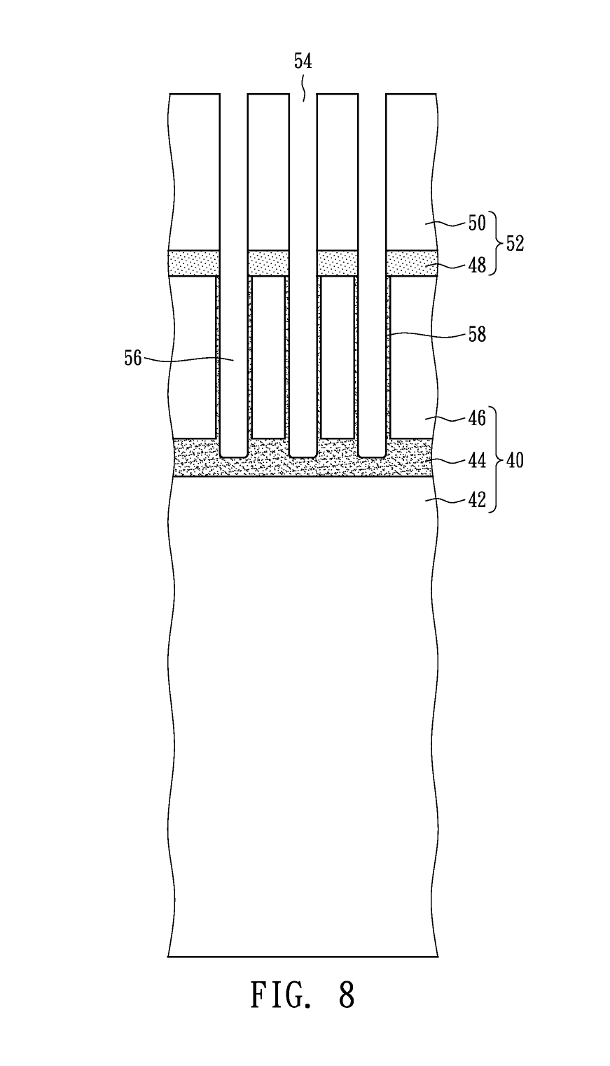

Referring to FIG. 7, a first etching process, preferably a dry etching process, is performed by using the first mask 52 as the etching mask to remove a portion of the substrate 40 under the openings 54 down to the interior of the insulation layer 44 to form several trenches 56. In particular, the dry etching process uses etching gases including hydrogen bromide, nitrogen trifluoride and oxygen to remove a portion of the second epitaxy layer 46 and the insulation layer 44 under the openings 54 such that the trenches 56 have a bottom in the insulation layer 44. Subsequently, a thermal treating process such as the rapid thermal process is performed to form a second mask 58 including silicon oxide on the inner sidewall of the trench 56, as shown in FIG. 8.

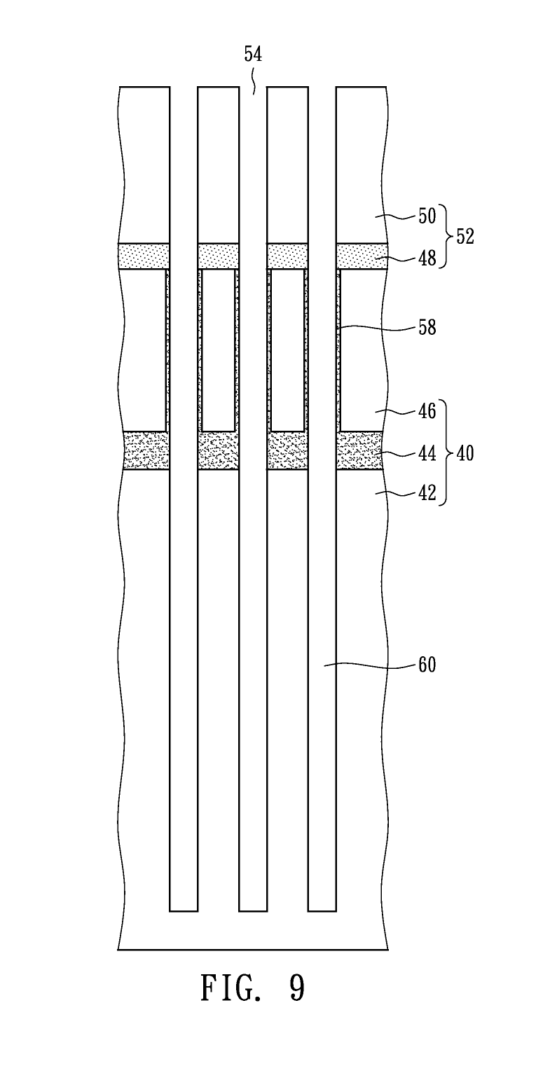

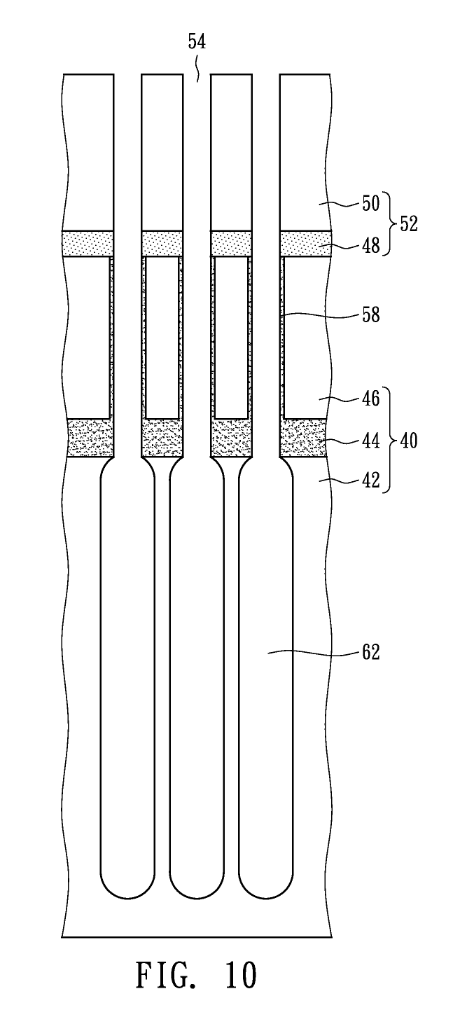

Referring to FIG. 9, a second etching process, preferably a dry etching process, is performed by using the first mask 52 and the second mask 56 as the etching mask to remove a portion of the substrate 40 under the openings 54 down to the interior of the first epitaxy layer 42 to form several deep trenches 60. In particular, the dry etching process uses etching gases including hydrogen bromide, nitrogen trifluoride and oxygen to remove a portion of the insulation layer 44 and the first epitaxy layer 42 under the openings 54 such that the deep trenches 60 have a bottom in the first epitaxy layer 42. Subsequently, a third etching process is performed to remove a portion of the first epitaxy layer 42 to enlarge the area of the deep trenches 60 so as to form the bottle-shaped deep trenches 62, as shown in FIG. 10. Preferably, the third etching process is a wet etching process using an etchant including dilute hydrofluoric acid and ammonium hydroxide.

The conventional technique form a damaged regions 28 at the interface of the two dry etching process areas, the damaged regions 28 have a higher etch rate compare with other area and the subsequent wet etching processes remove the damaged regions 28 easily by over-etching such that the bottle-shaped deep trenches 10 are connected to each other rather than isolated from each other. In contrast, the present invention uses a silicon-on-insulator substrate 40 to prepare the bottle-shaped deep trench 62 and the interface of the two dry etching process areas is controlled to be in the interior of the insulation layer 44 of the silicon-on-insulator substrate 40. The subsequent wet etching process only selectively removes the first epitaxy layer 42 of the silicon-on-insulator substrate 40, without etching the insulation layer 44 substantially. Consequently, even if the two dry etching processes actually form a damaged region in the insulation layer 44, the subsequent wet etching process will not remove the damaged region in the insulation layer 44 by over-etching. As a result, the present invention can prevent the bottle-shaped deep trenches 62 from connecting to each other due to over-etching.

The above-described embodiments of the present invention are intended to be illustrative only. Numerous alternative embodiments may be devised by those skilled in the art without departing from the scope of the following claims.

What is claimed is:

1. A method for preparing a bottle-shaped deep trench, comprising the steps of:
providing a substrate including a first epitaxy layer, an insulation layer positioned on the first epitaxy layer and a second epitaxy layer positioned on the insulation layer;
forming a first mask with at least one opening on the substrate;
performing a first etching process to remove a portion of the substrate under the opening down to the interior of the insulation layer to form a trench;
performing a thermal treating process to form a second mask on the inner sidewall of the trench;
performing a second etching process to remove a portion of the substrate under the opening down to the interior of the first epitaxy layer to form a deep trench; and
performing a third etching process to remove a portion of the first epitaxy layer to form a bottle-shaped deep trench.

2. The method for preparing a bottle-shaped deep trench of claim 1, wherein the step of forming a first mask with at least one opening on the substrate includes:
forming a silicon nitride layer on the second epitaxy layer;
forming a dielectric layer on the silicon nitride layer; and
performing a lithographic process to form the opening in the silicon nitride layer and the dielectric layer.

3. The method for preparing a bottle-shaped deep trench of claim 2, wherein the dielectric layer is a borosilicate glass layer.

4. The method for preparing a bottle-shaped deep trench of claim 1, wherein the substrate is a silicon-on-insulator substrate.

5. The method for preparing a bottle-shaped deep trench of claim 1, wherein the first etching process is a dry etching process.

6. The method for preparing a bottle-shaped deep trench of claim 1, wherein the first etching uses etching gases including hydrogen bromide, nitrogen trifluoride and oxygen.

7. The method for preparing a bottle-shaped deep trench of claim 1, wherein the second etching process is a dry etching process.

8. The method for preparing a bottle-shaped deep trench of claim 1, wherein the second etching uses etching gases including hydrogen bromide, nitrogen trifluoride and oxygen.

9. The method for preparing a bottle-shaped deep trench of claim 1, wherein the third etching process is a wet etching process.

10. The method for preparing a bottle-shaped deep trench of claim 1, wherein the third etching process uses an etchant including hydrofluoric acid and ammonium hydroxide.

11. The method for preparing a bottle-shaped deep trench of claim 1, wherein the thermal treating process is a rapid thermal process.

12. The method for preparing a bottle-shaped deep trench of claim 1, wherein the second mask includes silicon oxide.

13. The method for preparing a bottle-shaped deep trench of claim 1, wherein the first etching process removes a portion of the second epitaxy layer and the insulation layer under the opening.

14. The method for preparing a bottle-shaped deep trench of claim 1, wherein the first etching process uses the first mask as the etching mask.

15. The method for preparing a bottle-shaped deep trench of claim 1, wherein the trench has a bottom in the insulation layer.

16. The method for preparing a bottle-shaped deep trench of claim 1, wherein the second etching process removes a portion of the insulation layer and the first epitaxy layer under the opening.

17. The method for preparing a bottle-shaped deep trench of claim 1, wherein the second etching process uses the first mask and the second mask as the etching mask.

18. The method for preparing a bottle-shaped deep trench of claim 1, wherein the deep trench has a bottom in the first epitaxy layer.

19. The method for preparing a bottle-shaped deep trench of claim 1, wherein the third etching process uses the first mask and the second mask as the etching mask.
